(19) United States
(12) Patent Application Publication
(10) Pub. No.: US 2016/0379879 A1
(43) Pub. Date: Dec. 29, 2016

(54) TUNGSTEN FILM FORMING METHOD

(71) Applicant: TOKYO ELECTRON LIMITED, Tokyo (JP)

(72) Inventors: Takanobu HOTTA, Yamanashi (JP); Yasushi AIBA, Yamanashi (JP)

(21) Appl. No.: 15/039,803

(22) PCT Filed: Nov. 21, 2014
(86) PCT No.: PCT/JP2014/080941

§ 371 Date: May 26, 2016

(30) Foreign Application Priority Data
Nov. 27, 2013 (JP) 2013-244835

(51) Int. Cl. H01L 21/768; C23C 16/455; H01L 21/285; C23C 16/14

(52) U.S. Cl. CPC H01L 21/76879; C23C 16/14; C23C 16/45527; H01L 21/28562; H01L 21/28568

(57) ABSTRACT

In a method for forming a tungsten film, a substrate to be processed is disposed in a processing chamber having a reduced pressure atmosphere. Then a reducing gas and a tungsten chloride gas as a tungsten source are supplied to the processing chamber simultaneously or alternately with a process of purging an inside of the processing chamber interposed therebetween. The substrate is heated and the tungsten chloride gas and the reducing gas react with each other on the heated substrate to form a tungsten film.

### CROSS REFERENCE

This application is a National Stage Application of, and claims priority to, PCT Application No. PCT/JP2014/080941, filed on Nov. 21, 2014, entitled “TUNGSTEN FILM FORMING METHOD,” which claims priority to Japanese Patent Application No. 2013-244835, filed on Nov. 27, 2013. The foregoing patent applications are herein incorporated by reference in their entireties for all purposes.

### FIELD OF THE INVENTION

The present invention relates to a tungsten film forming method.

### BACKGROUND OF THE INVENTION

In a semiconductor device manufacturing process, tungsten is used as a material for filling a via hole between wirings or a contact hole formed on a semiconductor wafer (hereinafter, simply referred to as “wafer”) that is an object to be processed, a material for an interdiffusion barrier, or the like.

As for a tungsten film forming method, a physical vapor deposition (PVD) method has been conventionally used. However, tungsten W is a high melting point metal and it is difficult in the PVD method to deal with a high step coverage required along with a recent trend toward miniaturization of devices. Therefore, a tungsten film is formed by using a chemical vapor deposition (CVD) method that does not require melting of tungsten W having a high melting point and can deal with the miniaturization of devices.

As for the tungsten film (CVD-tungsten film) forming method using CVD, there is generally used a method for allowing reaction between tungsten hexafluoride (WF₆) as a source gas and H₂ gas as a reducing gas on a wafer, which is expressed by a reaction scheme WF₆+3H₂→W+6HF (see, e.g., Japanese Patent Application Publication Nos. 2003-193233 and 2004-273764). In addition, recently, an atomic layer deposition (ALD) method for alternately supplying WF₆ gas and a reducing gas has attracted attention as a technique for providing a higher step coverage.

However, recently, as miniaturization of a design rule advances, the devices may be adversely affected by fluorine in the case of using a source material containing fluorine.

As for a processing gas for forming a CVD-W film that does not contain fluorine, tungsten carbonyl (W(CO)₆) is known (see Japanese Patent Application Publication Nos. H2-225670, H4-173976, and H4-27136). In addition, in Japanese Patent Application Publication No. 2006-28572, tungsten hexachloride (WCl₆), oxyhalogen tungsten or the like, other than W(CO)₆, is disclosed as a W-based film forming material that does not contain F.

However, with respect to a W film formation using a film forming material that does not contain fluorine, there is no example of mass production. WF₆ is currently used as a tungsten film forming material while studying various measures.

The tungsten film is formed on a predetermined film such as an interlayer insulating film or the like with a barrier metal film interposed therebetween. However, the barrier metal film becomes thinner by the miniaturization of semiconductor devices. Therefore, a film formed below the barrier metal film may be damaged by fluorine depending on a material of the corresponding film. Accordingly, it may be undesirable to use WF₆ gas containing fluorine in spite of the various measures.

### SUMMARY OF THE INVENTION

In view of the above, the present invention provides a tungsten film forming method capable of forming a practical tungsten film by using a tungsten source that does not contain fluorine by a CVD method or an ALD method.

In accordance with an aspect, there is provided a tungsten film forming method. In the method, a substrate to be processed is disposed in a processing chamber having a reduced pressure atmosphere. Next, a tungsten chloride gas as a tungsten source and a reducing gas are supplied into the processing chamber simultaneously or alternately with a process of purging an inside of the processing chamber interposed therebetween. The substrate is heated. A tungsten film is formed by causing the tungsten chloride gas and the reducing gas to react with each other on the heated substrate.

Conditions of a temperature of the substrate and a pressure in the processing chamber are desirably set such that an underlying layer of a tungsten film to be formed is not etched by the tungsten chloride. WCl₆ can be used as the tungsten chloride.

The substrate has preferably a TiN film or a TiSiN film as the underlying layer of the tungsten film.

As a condition for generating the effective film-forming reaction, the temperature of the substrate is 400° C. or above and the pressure in the processing chamber is 5 Torr (667 Pa) or above. It is preferably a high pressure-high temperature condition of 400° C. or above and 10 Torr (1333 Pa) or above. Preferably, the temperature of the substrate is 500° C. or above and the pressure in the processing chamber is 5 Torr or above.

The reducing gas is preferably at least one of H₂ gas, SiH₄ gas, B₂H₆ gas, and NH₃ gas. Preferably, initial film formation is performed by using SiH₄ gas or B₂H₆ gas as the reducing gas and then main film formation is performed by using H₂ gas as the reducing gas.

In accordance with another aspect, there is provided a storage medium storing a computer-executable program for controlling a film forming apparatus. The program, when executed on a computer, controls the film forming apparatus to perform a tungsten film forming method. In the method, a substrate to be processed is disposed in a processing chamber having a reduced pressure atmosphere. Next, a tungsten chloride gas as a tungsten source and a reducing gas are supplied into the processing chamber simultaneously or alternately with a process of purging an inside of the processing chamber interposed therebetween. The substrate is heated. A tungsten film is formed by causing the tungsten chloride gas and the reducing gas to react with each other on the heated substrate.

In the present invention, a practical tungsten film having excellent characteristics can be formed by a CVD method or an ALD method while using WCl₆ as a tungsten source that does not contain fluorine.

### BRIEF DESCRIPTION OF THE DRAWINGS

FIG. 1 is a cross sectional view showing an example of a film forming apparatus for performing a tungsten film forming method according to an embodiment of the present invention.

FIG. 2 shows a processing recipe for film formation using a CVD method.

FIG. 3 shows a processing recipe for film formation using an ALD method.

FIG. 4A shows relation between a wafer temperature, a pressure in a chamber, and a film forming rate in the case of forming a tungsten film by the CVD method while using a TiN film as an underlying layer in a test example 1.

FIG. 4B shows relation between a wafer temperature, a pressure in the chamber, and a film forming rate in the case of forming a tungsten film by the CVD method while using a H₂-reduced W film, as an underlying layer in the test example 1.

FIG. 5A shows relation between a pressure in the chamber, a flow rate of a carrier N₂ gas, and a film forming rate in the case of forming a tungsten film by the CVD method while using a TiN film as an underlying layer in a test example 2.

FIG. 5B shows relation between a pressure in the chamber, a flow rate of the carrier N₂ gas, and a film forming rate in the case of forming a tungsten film by the CVD method while using a H₂-reduced W film, as an underlying layer in the test example 2.

FIG. 6 shows relation between a WCl₆ gas supply period and an etching depth of a TiN film in the case of varying a flow rate of the carrier N₂ gas in a test example 3.

FIG. 7 shows relation between a wafer temperature, a pressure in the chamber, and a film forming rate per one cycle in the case of forming a tungsten film by the ALD method while using a TiN film as an underlying layer in a test example 4.

FIG. 8 shows relation between a wafer temperature, a pressure in the chamber, and a film forming rate per one cycle in the case of forming a tungsten film by the ALD method while using a TiN film as an underlying layer in a test example 5.

FIG. 9 shows relation between the pressure in the chamber and the film forming rate per one cycle in the case of setting the wafer temperature to 500° C. in the test example 5.

FIG. 10A shows relation between a film thickness of a tungsten film and a resistivity in the case of forming a tungsten film by the CVD method while using a TiN film and a H₂-reduced W film as, an underlying layer in a test example 6.

FIG. 10B shows relation between a film thickness of a tungsten film and a resistivity in the case of forming a tungsten film by the CVD method while using a SiH₄-reduced W film and a B₂H₆-reduced W film, as an underlying layer in the test example 6.

FIG. 11 shows SEM images of cross sections of tungsten films formed on the respective underlying layers in the test example 6.

FIG. 12 shows a film formation rate per one cycle in the case of forming a tungsten film by the ALD method while using a TiN film, a TiSiN film and a SiO₂ film as an underlying layer in a test example 7.

FIG. 13 shows an SEM image of a cross section of a tungsten film in the case of forming a tungsten film in a hole having an aspect ratio of 60 in a test example 8.

FIG. 14A shows a result of secondary ion mass spectrometry (SIMS) analysis of impurities in a depth direction of a tungsten film formed in a test example 9 which is presented as the number of atoms per 1 cm³.

FIG. 14B shows the result of the SIMS analysis of impurities in the depth direction of the tungsten film formed in the test example 9 which is presented as atomic %.

### DETAILED DESCRIPTION OF THE EMBODIMENTS

<Circumstances that have Led to Present Invention>

Prior to description of embodiments of the present invention, circumstances that have led to the present invention will be described.

The present inventors paid attention to WCl₆ that is halogenated tungsten similar to WF₆ as a tungsten film forming material that does not fluorine.

WCl₆ is the halogenated tungsten similar to WF₆. It has been believed that WCl₆ and WF₆ exhibit the same behavior in film formation. However, it is actually difficult to form a practical tungsten film at a mass production level using WCl₆ by a CVD method or an ALD method.

Japanese Patent Application Publication No. 2006-28572 discloses that WCl₆, that is tungsten chloride, can be used as a tungsten source. However, there is disclosed a special method referred to as a CAT-ALD method that is combination of a CAT method (catalytic method) and an ALD method. In this method, a tungsten nitride film is formed. There is not disclosed a tungsten film forming method using a simple CVD method or a simple ALD method. Further, there is not disclosed an embodiment using WCl₆.

As a result of repeated study, the present inventors have found that the behavior in the film formation using WCl₆ is considerably different from the behavior in the film formation using WF₆ and also that a practical tungsten film having excellent characteristics can be formed by a CVD method or an ALD method under the condition suitable for the behavior in the film formation in the case of using WCl₆ as a tungsten source. As a result, the present invention has been conceived.

As a result of further study, the present inventors have found that when using WCl₆ as a tungsten source, even under the condition that a tungsten film can be formed using WF₆, there are temperature and pressure conditions which allow etching of an underlying layer of a tungsten film formed using WCl₆ as a tungsten source and also that it is preferable to set a temperature-pressure condition out of the temperature-pressure conditions which cause the etching reaction.

Hereinafter, embodiments will be described with reference to the accompanying drawings.

<Film Forming Apparatus>

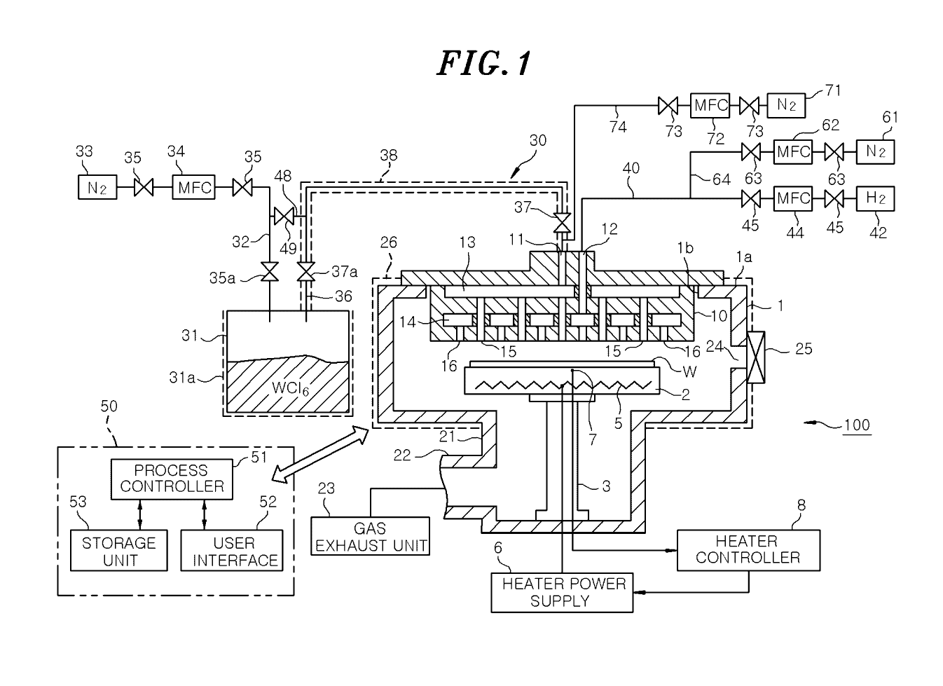

FIG. 1 is a cross sectional view showing an example of a film forming apparatus for performing a tungsten film forming method according to an embodiment of the present invention.

As shown in FIG. 1, a film forming apparatus 100 includes an airtight cylindrical chamber 1. In the chamber 1, a susceptor 2 for horizontally supporting a wafer W that is a substrate to be processed is supported by a cylindrical supporting member 3 extending from a bottom portion of a gas exhaust chamber, which will be described later, to a lower central portion of the chamber 1. The susceptor 2 is made of ceramic, e.g., AlN or the like. A heater 5 is embedded in the susceptor 2. A heater power supply 6 is connected to the heater 5. A thermocouple 7 is provided near a top surface of the susceptor 2. A signal of the thermocouple 7 is transmitted to a heater controller 8. The heater controller 8 transmits an instruction to the heater power supply 6 based on the signal of the thermocouple 7 and controls the temperature of a wafer W to a predetermined level by controlling the heating of the heater 5. Three wafer elevation pins (not shown) are provided at the susceptor 2 so as to protrude beyond and retract below the top surface of the susceptor 2. When the wafer W is transferred, the elevation pins protrude beyond the top surface of the susceptor 2. Further, the susceptor 2 is vertically movable by an elevation unit (not shown).

A circular hole 1b is formed in a ceiling wall la of the chamber 1. A shower head 10 is inserted into the chamber 1 through the hole 1b so as to protrude inside the chamber 1. The shower head 10 injects into the chamber 1 WCl₆ gas serving as a film forming source gas supplied from a gas supply unit 30 to be described later. A first introduction line 11 for introducing the WCl₆ gas and N₂ gas as a purge gas and a second introduction line 12 for introducing H₂ gas as a reducing gas and N₂ gas as a purge gas are provided at an upper portion of the shower head 10.

Inside the shower head 10, there are provided an upper space 13 and a lower space 14. The first introduction line 11 is connected to the upper space 13. First gas injection lines 15 extend from the space 13 to a bottom surface of the shower head 10. The second introduction line 12 is connected to the lower space 14. Second gas injection lines 16 extend from the lower space 14 to the bottom surface of the shower head 10. In other words, the shower head 10 is configured to independently inject WCl₆ gas as a film forming source gas and H₂ gas as a reducing gas through the injection lines 15 and 16.

A gas exhaust chamber 21 protruding downward is provided at a bottom wall of the chamber 1. A gas exhaust line 22 is connected to a side surface of the gas exhaust chamber 21. A gas exhaust unit 23 including a vacuum pump, a pressure control valve and the like is connected to the gas exhaust line 22. By operating the gas exhaust unit 23, a pressure in the chamber 1 can be set to a predetermined vacuum level.

A loading/unloading port 24 for loading/unloading a wafer and a gate valve 25 for opening/closing the loading/unloading port 24 are provided at a sidewall of the chamber 1. A heater 26 is provided at a wall of the chamber 1, so that a temperature of an inner wall of the chamber 1 can be controlled during the formation of a film.

The gas supply unit 30 includes a film forming material tank 31 which accommodates WCl₆ as a source material for film formation. WCl₆ exists in a solid state at a room temperature and thus is accommodated in a solid state in the film forming material tank 31. A heater 31a is provided around the film forming material tank 31. The film forming source material, WCl₆, in the tank 31 is heated to a proper temperature to be sublimated. As tungsten chloride, WCl₅ may be used. WCl₅ exhibits substantially the same behavior as that of WCl₆.

A carrier gas line 32 for supplying N₂ gas as a carrier gas is inserted into the film forming material tank 31 through the top thereof. The carrier gas line 32 is connected to a N₂ gas supply source 33. A mass flow controller 34 which is a flow rate controller and valves 35 disposed at an upstream side and a downstream side thereof are provided at the carrier gas line 32. One end of a source gas delivery line 36 is inserted into the film forming material tank 31 through the top thereof. The other end of the source gas delivery line 36 is connected to the first introduction line 11 of the shower head 10. A valve 37 is disposed at the source gas delivery line 36. A heater 38 for preventing condensation of WCl₆ gas as a film forming source gas is provided around the source gas delivery line 36. WCl₆ gas sublimated in the film forming material tank 31 is transferred by N₂ gas as a carrier gas and supplied into the shower head 10 through the source gas delivery line and the first introduction line 11. The source gas delivery line 36 is also connected to a N₂ gas supply source 71 for supplying N₂ gas (purge N₂) as a purge gas via a bypass line 74. A mass flow controller 72 which is a flow rate controller and valves 73 disposed at an upstream side and a downstream side thereof are provided at the bypass line 74. The N₂ gas from the N₂ gas supply source 71 is used as a purge gas at the source gas line side.

The carrier gas line 32 and the source gas delivery line 36 are connected by a bypass line 48. A valve 49 is provided at the bypass line 48. Valves 35a and 37a are respectively provided at the carrier gas line 32 and the source gas delivery line 36 at a downstream side of the connecting portion of the bypass line 48. By closing the valves 35a and 37a and opening the valve 49, N₂ gas from the N₂ gas supply source 33 can be supplied through the carrier gas line 32 and the bypass line 48 to the source gas delivery line 36 to purge the source gas delivery line 36. The carrier gas and the purge gas are not limited to N₂ gas and may be another inert gas such as Ar gas or the like.

A line 40 serving as a H₂ gas line is connected to the second introduction line 12 of the shower head 10. The line 40 is connected to a H₂ gas supply source 42 for supplying H₂ gas as a reducing gas. The line 40 is also connected to a N₂ gas supply source 61 for supplying N₂ gas as a purge gas (purge N₂) via a line 64. A mass flow controller 44 which is a flow rate controller and valves 45 disposed at an upstream side and a downstream side thereof are provided at the line 40. A mass flow controller 62 which is a flow rate controller and valves 63 disposed at an upstream side and a downstream side thereof are provided at the line 64. The N₂ gas from the N₂ gas supply source 61 is used as a purge gas supplied through the second introduction line 12. The reducing gas is not limited to H₂ gas and may be SiH₄ gas, B₂H₆ gas, or the like. Two or more of H₂ gas, SiH₄ gas and B₂H₆ gas may be supplied. Further, other reducing gases, e.g., PH₃ gas and SiH₂Cl₂ gas, may be used.

The film forming apparatus 100 includes a control unit 50 for controlling the respective components, specifically the valves, the power supply, the heaters, the pump and the like. The control unit 50 includes a process controller 51 having a microprocessor (computer), a user interface 52, and a storage unit 53. The respective components of the film forming apparatus 100 are electrically connected to the process controller 51 and controlled by the process controller 51. The user interface 52 is connected to the process controller 51. The user interface 52 includes a keyboard through which an operator inputs a command or the like to manage the respective components of the film forming apparatus 100, a display for visually displaying an operation state of the respective components of the film forming apparatus 100, and the like. The storage unit 53 is connected to the process controller 51. The storage unit 53 stores a control program for realizing various processes performed by the film forming apparatus 100 under the control of the process controller 51, a control program, i.e., a processing recipe, for controlling the respective components of the film forming apparatus 100 to perform predetermined processes based on the processing conditions, various database and the like. The processing recipe is stored in a storage medium (not shown) in the storage unit 53. The storage medium may be a fixed medium such as a hard disk or the like, or may be a portable medium such as a CDROM, a DVD, a flash memory or the like. Alternatively, the processing recipe may be appropriately transmitted from another device through, e.g., a dedicated line.

If necessary, a processing recipe is retrieved from the storage unit 53 by an instruction from the user interface 52 or the like and executed by the process controller 51. Accordingly, a desired process is performed in the film forming apparatus 100 under the control of the process controller 51.

<Embodiment of Film Forming Method>

Hereinafter, an embodiment of a film forming method performed by the film forming apparatus 100 configured as described above will be described.

First, the gate valve 25 is opened. Next, the wafer W is loaded into the chamber 1 through the loading/unloading port 11 by a transfer unit (not shown) and mounted on the susceptor 2 heated to a predetermined temperature by the heater 5. Then, the pressure in the chamber 1 is decreased to a predetermined vacuum level, and a tungsten film is formed by a CVD method or an ALD method as will be described below. As the wafer W, it is possible to use a wafer having a barrier metal film (e.g., a TiN film or a TiSiN film) as an underlying layer on a surface of an interlayer insulating film having a recess such as a trench or a hole, or on a surface of a thermal oxide film. A tungsten film has a poor adhesive strength to the thermal oxide film and the interlayer insulating film and requires a long incubation time. Therefore, it is difficult to form a tungsten film on the interlayer insulating film and on the thermal oxide film.

However, the formation of the tungsten film can become easier by using, as an underlying layer, a TiN film or a TiSiN film. The underlying layer is not limited thereto.

(Film Formation Using CVD Method)

First, the film formation using a CVD method will be described.

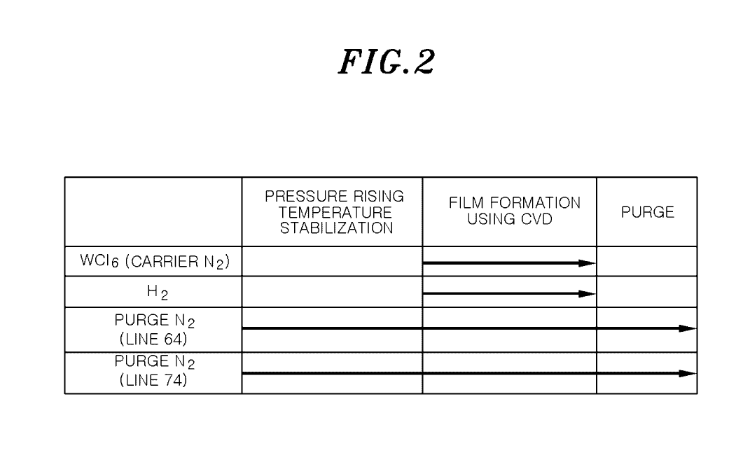

FIG. 2 shows a processing recipe for the film formation using a CVD method. First, the valves 37, 37a, and 45 are closed and the valves 63 and 73 are made to open. Accordingly, N₂ gases (purge N₂) as purge gases are supplied from the N₂ gas supply sources 61 and 71 into the chamber 1 through the lines 64 and 74 to increase a pressure in the chamber 1. A temperature of the wafer W on the susceptor 2 is stabilized.

After the pressure in the chamber 1 reaches a predetermined level, the valves 37 and 37a are opened in a state where the N₂ gases are supplied from the N₂ gas supply sources 61 and 71, so that N₂ gas (carrier N₂) as a carrier gas is supplied into the film forming material tank 31 to carry WCl₆ gas sublimated in the film forming material tank 31 into the chamber 1. H₂ gas is also supplied from the H₂ gas supply source 42 into the chamber 1 by opening the valve 45. Then, the reaction between the WCl₆ gas as a tungsten source gas and the H₂ gas as a reducing gas occurs on the underlying layer at the surface of the wafer W, thereby forming a tungsten film. When WCl₅ gas is used as a tungsten source gas, a tungsten film is formed through the same process.

The film forming process is continuously performed until the thickness of the tungsten film reaches a predetermined level. Thereafter, the valve 45 is closed to stop the supply of H₂ gas, and N₂ gas as a purge gas is supplied into the chamber 1 to purge the inside of the chamber 1. In this manner, the film formation using a CVD is completed. A thickness of the tungsten film can be controlled by controlling a period of time for film formation.

(Film Formation Using ALD Method)

Hereinafter, the film formation using an ALD method will be described.

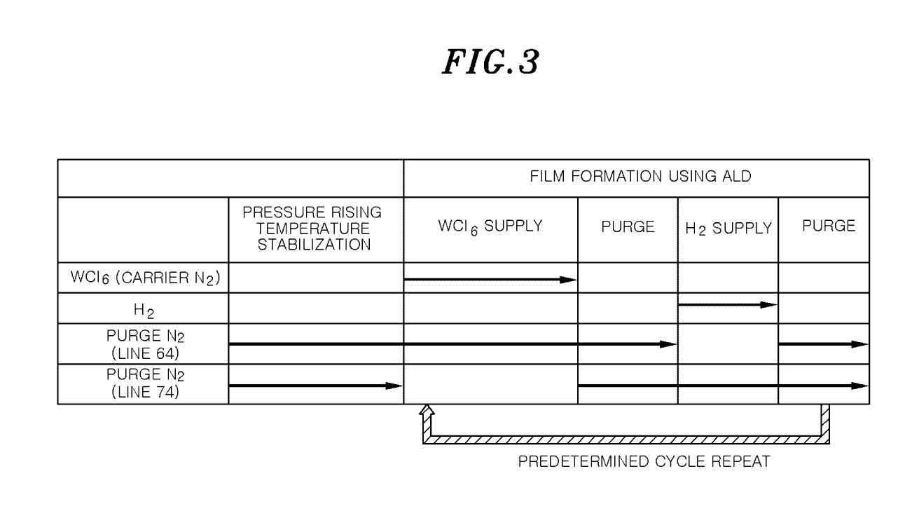

FIG. 3 shows a processing recipe for the film formation using an ALD method. As in the case of employing the CVD method, first, the valves 37, 37a, and 45 are closed and the valves 63 and 73 are made to open. Accordingly, N₂ gases as purge gases (purge N₂) are supplied from the N₂ gas supply sources 61 and 71 into the chamber 1 to increase a pressure in the chamber 1. A temperature of the wafer W on the susceptor 2 is stabilized.

After the pressure in the chamber 1 reaches a predetermined level, in a state where the N₂ gas is supplied from the N₂ gas supply source 61 through the line 64, the supply of the purge N₂ gas through the line 74 is stopped by closing the valve 73, and the valves 37 and 37a are opened so that a carrier N₂ gas is supplied into the film forming material tank 31 to carry WCl₆ gas sublimated in the film forming material tank 31 into the chamber 1 in a short period of time. The WCl₆ gas is adsorbed on the underlying layer formed at the surface of the wafer W (WCl₆ gas supply step). Thereafter, the valves 37 and 37a are closed to stop the supply of the WCl₆ gas. At the same time, the purge N₂ gas is supplied into the chamber 1 by opening the valve 73, so that a residual WCl₆ gas in the chamber 1 is purged (purge step).

Next, in a state where the purge N₂ gas is supplied from the N₂ gas supply source 71 through the line 74, the supply of the purge N₂ gas through the line 64 is stopped by closing the valve 63. H₂ gas is supplied from the H₂ gas supply source 42 into the chamber 1 in a short period of time by opening the valve 45. The supplied H₂ gas reacts with WCl₆ adsorbed on the surface of the wafer W (H₂ gas supply step). Next, the valve 45 is closed to stop the supply of the H₂ gas and the purge N₂ gas is supplied, in addition to the purge N₂ gas supplied through the line 74, into the chamber 1 by opening the valve 63, so that a residual H₂ gas in the chamber 1 is purged (purge step).

A thin tungsten unit film is formed by performing one cycle of the WCl₆ gas supply step, the purge step, the H₂ gas supply step, and the purge step. By repeating the cycle multiple times, a tungsten film having a desired thickness is formed. A thickness of the tungsten film can be controlled by the repetition number of the cycle. When WCl₅ gas is used as the tungsten source gas, a tungsten film is formed through the same process.

(Film Formation Conditions)

When WCl₆ is used as a tungsten source, since WCl₆ gas has an etching function, the underlying layer of the tungsten film is etched by the WCl₆ gas depending on temperature and pressure conditions, thereby making it difficult to form the tungsten film. Accordingly, it is desirable to set a temperature and pressure condition out of the temperature and pressure conditions which cause the etching reaction. More specifically, since film formation reaction or etching reaction does not occur at a low temperature, it is necessary to set a temperature to be high enough to cause the film formation reaction. Further, since an etching reaction may be caused at a low pressure under a high temperature condition that allows for film formation reaction, it is desirable to employ a high temperature and high pressure condition.

Specifically, although the temperature-pressure condition depends on the types of the underlying layer, it is preferable to set a wafer temperature (susceptor surface temperature) to 400° C. or above and a pressure in the chamber to 5 Torr (667 Pa) or above in both of the CVD method and the ALD method. This is because the film formation reaction hardly occurs at a wafer temperature lower than 400° C. and the etching reaction easily occurs at a pressure lower than 5 Torr and at a wafer temperature of 400° C. or above. When the wafer temperature is 400° C., the amount of the formed film tends to be reduced at a pressure of 5 Torr, but a sufficient amount of the formed film can be obtained at a pressure of 10 Torr (1333 Pa). Therefore, it is preferable to set a pressure in the chamber to 10 Torr or above when the wafer temperature is 400° C. or above. When the wafer temperature is 500° C., the amount of the formed film is increased and a sufficient amount of the formed film can be obtained at 5 Torr. Accordingly, it is more preferable to set the wafer temperature to 500° C. or above and the pressure in the chamber to 5 Torr or above. The amount of the formed film is increased as the temperature is increased, but the temperature has an actual upper limit of about 800° C. in view of the equipment constraints and reactivity. The wafer temperature is preferably 400° C. to 700° C., and more preferably 400° C. to 650° C. The amount of the formed film is increased as the pressure is increased but the pressure also has an actual upper limit of 100 Torr (13333 Pa) in view of the apparatus constraints and reactivity. The pressure in the chamber is preferably 10 Torr to 40 Torr (1333 Pa to 5333 Pa). The preferable conditions vary depending on the structure of the apparatus or other conditions.

Preferable ranges of other conditions are as follows.

CVD Method

Carrier N₂ gas flow rate: 20 to 1000 sccm (mL/min)

(WCl₆ gas flow rate: 0.25 to 30 sccm (mL/min))

H₂ gas flow rate: 500 to 5000 sccm (mL/min)

Temperature of film forming material tank: 130 to 190° C.

ALD Method

Carrier N₂ gas flow rate: 20 to 500 sccm (mL/min)

(WCl₆ gas flow rate: 0.25 to 15 sccm (mL/min))

WCl₆ gas supply period (per once): 0.05 to 10 sec

H₂ gas flow rate: 500 to 5000 sccm (mL/min)

H₂ gas supply period (per once): 0.1 to 10 sec

Temperature of film formation source tank: 130 to 190° C.

In both of the CVD method and the ALD method, SiH₄ gas, B₂H₆ gas and NH₃ gas can be used, other than H₂ gas, as a reducing gas. In the case of using such gases, the desirable film formation can be performed under the same condition. In order to further reduce the impurities in the film, it is preferable to use H₂ gas. Further, by using NH₃ gas, excellent reactivity can be obtained and a film forming rate can be increased. As described above, another reducing gas, e.g., PH₃ gas or SiH₂Cl₂ gas, may also be used.

(Effect of Embodiment)

With the above film forming method, a practical tungsten film having excellent characteristics can be formed. Specifically, it is possible to obtain a tungsten film having a low concentration of impurities such as Cl, C, N, O and the like and a resistivity substantially the same as that of a conventional tungsten film using WF₆ as a tungsten source. Further, a tungsten film having a good step coverage can be formed.

<Another Embodiment of Film Forming Method>

Hereinafter, another embodiment of the film forming method will be described.

In the present embodiment, an initial tungsten film is formed by a CVD method or an ALD method on a barrier film (TiN film or TiSiN film) formed as an underlying layer on a thermal oxide film or an interlayer insulating film and, then, a main tungsten film is formed by a CVD method or an ALD method. By forming the main tungsten film on the initial tungsten film, the condition in which the main tungsten film can be formed can be extended. The film thickness of the initial tungsten film is preferably 3 to 10 nm.

In this case, it is preferable to use SiH₄ gas or B₂H₆ gas as a reducing gas during the formation of the initial tungsten film and use H₂ gas as a reducing gas during the formation of the main tungsten film. As a consequence, a tungsten film having a resistivity lower than that of a tungsten film directly formed on the underlying layer by H₂ reduction can be formed without increasing impurities. This is because a size of crystal grain of tungsten is increased by forming a main tungsten film on the initial tungsten film formed by using SiH₄ gas or B₂H₆ gas as a reducing gas.

### TEST EXAMPLE

Hereinafter, test examples will be described.

### Test Example 1

Here, a film forming area in the case of employing a CVD method was examined. A tungsten film was formed by a CVD method by using the film forming apparatus shown in FIG. 1. At this time, a TiN film and a tungsten film (H₂-reduced W film) formed by using WCl₆ gas as a source gas and H₂ gas as a reducing gas were used as an underlying layer. Further, a wafer temperature was varied within a range from 300 to 500° C. and a pressure in the chamber was varied within a range from 5 Torr to 30 Torr. Other conditions were as follows. A flow rate of the carrier N₂ gas for supplying WCl₆ gas was set to 50 sccm. A flow rate of the H₂ gas was set to 1500 sccm. A flow rate of the WCl₆ gas was about 1.1% of that of the carrier N₂ gas.

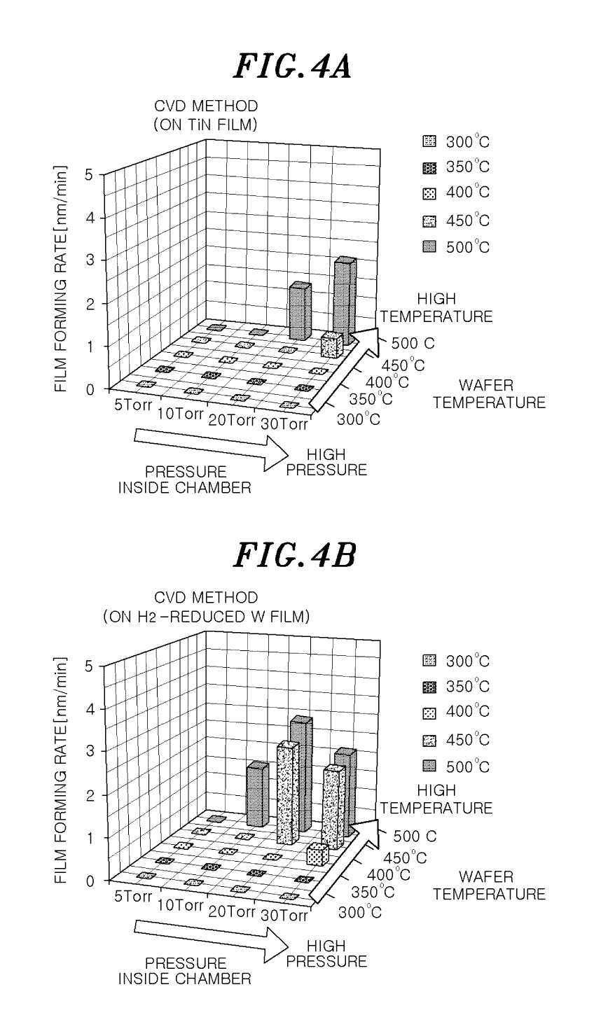

FIGS. 4A and 4B show the relation between the wafer temperature, the pressure in the chamber, and the film forming rate. FIG. 4A shows the case in which the underlying layer was a TiN film. FIG. 4B shows the case in which the underlying layer was a H₂-reduced W film.

As shown in FIGS. 4A and 4B, when the underlying layer was a TiN film, the film formation occurred at the wafer temperature of 450° C. or above and at the pressure in the chamber of 20 Torr or above. When the underlying layer was a H₂-reduced W film, the film formation occurred at the wafer temperature of 400° C. or above and the pressure in the chamber of 10 Torr or above. Accordingly, it has been found that the film forming rate is increased as the temperature and the pressure are increased.

### Test Example 2

Here, as in the test example 1, a tungsten film was formed by a CVD method by using the film forming apparatus shown in FIG. 1. At this time, a TiN film and a H₂-reduced W film formed by using WCl₆ gas as a source gas and H₂ gas as a reducing gas were used as an underlying layer. Further, a wafer temperature was fixed to 500° C. and a flow rate of H₂ gas was fixed to 1500 sccm. Moreover, a pressure in the chamber was varied within a range from 5 Torr to 30 Torr and a flow rate of the carrier N₂ gas was varied within a range from 20 sccm to 500 sccm (corresponding to the flow rate of WCl₆ gas ranging from 0.23 sccm to 5.75 sccm). As in the test example 1, the flow rate of WCl₆ gas was about 1.1% of the flow rate of carrier N₂ gas.

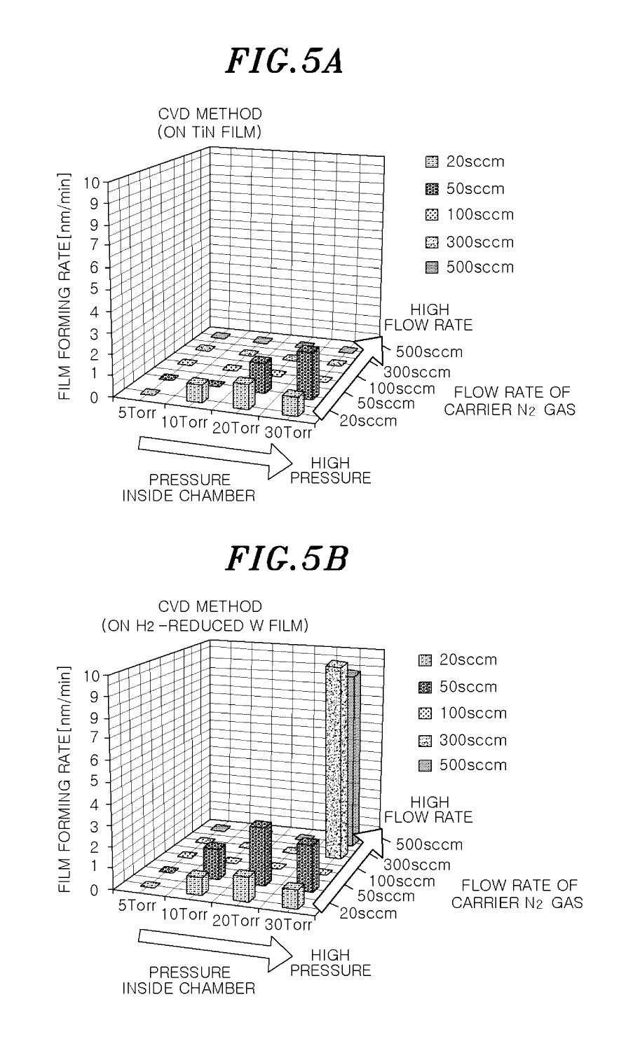

FIGS. 5A and 5B show the relation between the pressure in the chamber, the flow rate of the carrier N₂ gas, and the film forming rate. FIG. 5A shows the case in which the underlying layer was a TiN film. FIG. 5B shows the case in which the underlying layer was a H₂-reduced W film.

As shown in FIG. 5A, in the case of using a TiN film as an underlying layer, the film formation occurred when the flow rate of the carrier gas was 50 sccm or less. However, the film formation did not occur when the flow rate of the carrier gas was greater than 50 sccm. Further, the flow rate of the carrier gas capable of allowing the film formation to occur was increased as the pressure was increased. This strongly indicates that the TiN film is etched as the flow rate of WCl₆ gas is increased.

Meanwhile, as shown in FIG. 5B, in the case of using a H₂-reduced W film as an underlying layer, the film forming rate was increased as the flow rate of the carrier N₂ gas, i.e., the flow rate of WCl₆ gas, was increased. Therefore, it has been found that the film forming rate is increased under a high pressure condition and a large flow rate condition. This is because the H₂-reduced W film is not etched by WCl₆ gas.

### Test Example 3

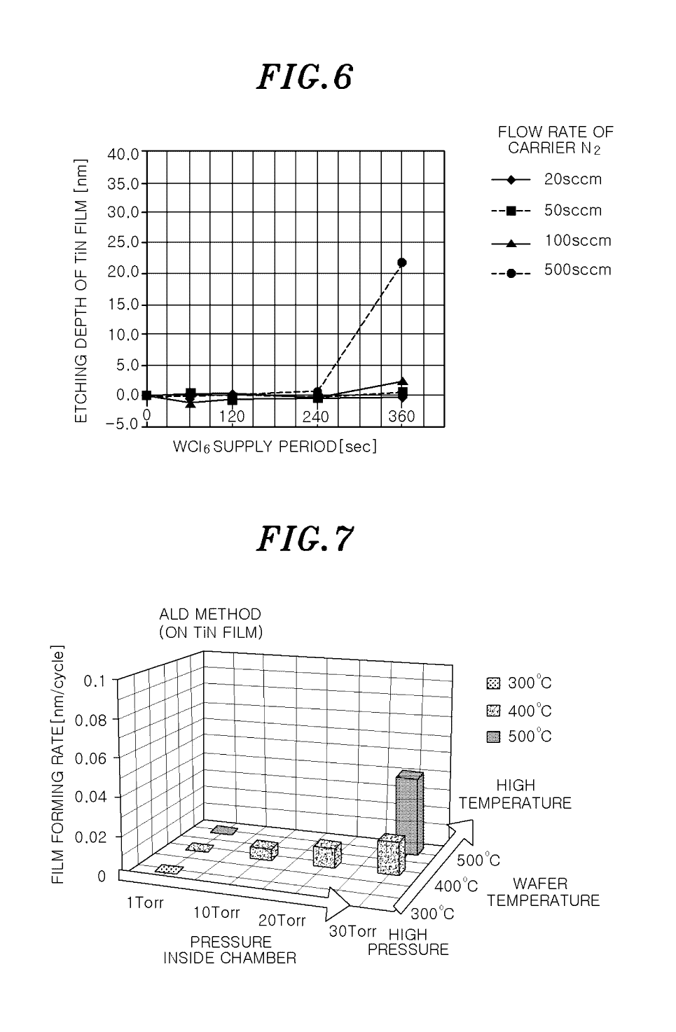

Next, the etching property of the TiN film as the underlying layer by WCl₆ gas was examined. Here, the relation between the WCl₆ gas supply period and the etching depth of the TiN film in the case of setting the wafer temperature to 300° C. and the pressure in the chamber to 30 Torr and varying the flow rate of the carrier N₂ gas within a range from 20 sccm to 500 sccm (corresponding to the flow rate of the WCl₆ gas which ranges from 0.23 sccm to 5.75 sccm) was examined. The result thereof is shown in FIG. 6. As shown in FIG. 6, the TiN film was etched by the WCl₆ gas and the etching depth was increased as the flow rate of the WCl₆ gas was increased. However, under the above temperature and pressure conditions, the incubation time of etching was long and the etching did not occur when the WCl₆ gas supply period was 240 sec or less.

### Test Example 4

Here, the film formation area in the case of employing an ALD method was examined. A tungsten film was formed by an ALD method by using the film forming apparatus shown in FIG. 1 while using a TiN film as an underlying layer and varying the wafer temperature to 300° C., 400° C. and 500° C. and the pressure in the chamber to 1 Torr, 10 Torr, 20 Torr and 30 Torr.

The other conditions were set as follows.

Flow rate of carrier N₂ gas: 50 sccm

Flow rate of H₂ gas: 1500 sccm

Duration of WCl₆ gas supply step (per once): 5 sec

Duration of H₂ gas supply step (per once): 5 sec

Duration of purge step (per once): 10 sec

FIG. 7 shows the relation between the wafer temperature, the pressure in the chamber, and the film forming rate per one cycle. As shown in FIG. 7, at the wafer temperature of 40017, the film formation occurred when the pressure in the chamber was 10 Torr or above, and it has been found that the film forming rate tends to be increased under a high temperature and high pressure condition. A highest film forming rate of 0.042 nm/cycle was obtained at the highest temperature of 500° C. and the highest pressure of 30 Torr in this test.

### Test Example 5

Here, the film formation area in the case of employing an ALD method was examined in detail. A tungsten film was formed by an ALD method by using the film forming apparatus shown in FIG. 1 while using a TiN film as an underlying layer and varying the wafer temperature to 300° C., 400° C. and 500° C. and the pressure in the chamber to 5 Torr, 10 Torr, 20 Torr, 30 Torr and 40 Torr. The other conditions were the same as those of the test example 4.

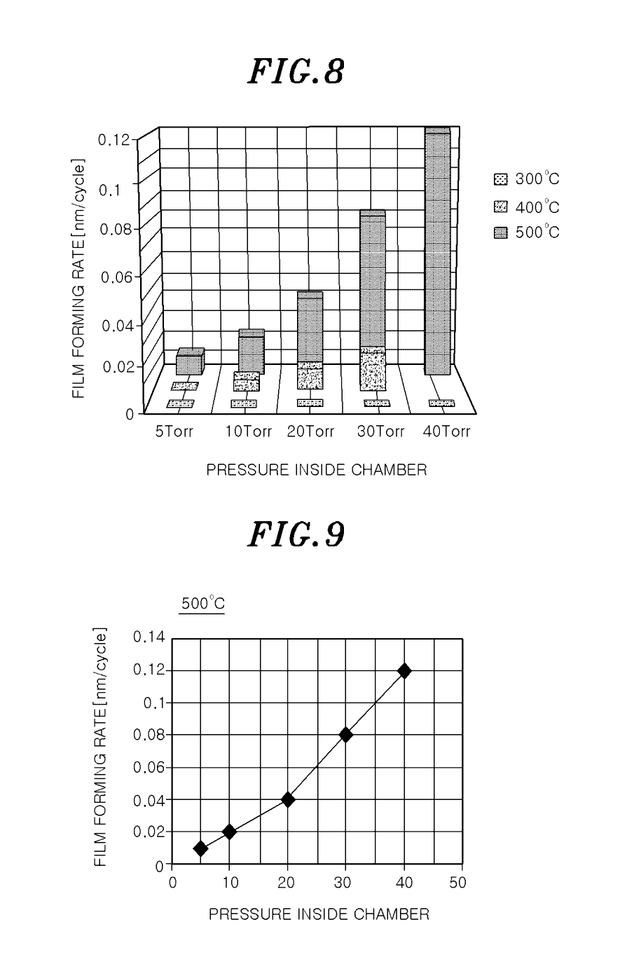

FIG. 8 shows the relation between the wafer temperature, the pressure in the chamber, and the film forming rate per one cycle. As shown in FIG. 8, at the wafer temperature of 300° C., the film formation did not occur at any pressure. At the wafer temperature of 400° C., the film formation occurred when the pressure was 10 Torr or above. At the wafer temperature of 500° C., the film formation occurred when the pressure was 5 Torr or above. It has been found that the film forming rate tends to be increased as the temperature and the pressure are increased. At the wafer temperature of 500° C., the film formation occurred when the pressure in a chamber was 5 Torr. At the wafer temperature of 400° C., the film formation occurred when the pressure in the chamber was 10 Torr. A highest film forming rate of 0.12 nm/cycle was obtained at the highest temperature of 500° C. and the highest pressure of 40 Torr in this test. The relation between the pressure in the chamber and the film forming rate per one cycle at the wafer temperature of 500° C. is separately shown in FIG. 9.

### Test Example 6

Here, the relation between the film thickness of the tungsten film formed by the CVD method and the resistivity of the film was examined. Tungsten films of different film thicknesses were formed by the CVD method by using the film forming apparatus shown in FIG. 1 and the resistivity of each film was measured. At this time, a TiN film, a tungsten film (H₂-reduced W film) formed by using H₂ gas as a reducing gas, a tungsten film (SiH₄-reduced W film) formed by using SiH₄ gas as a reducing gas, and a tungsten film (B₂H₆-reduced W film) formed by using B₂H₆ gas as a reducing gas were used as an underlying layer. Further, the wafer temperature was set to 500° C. and the pressure in the chamber was set to 30 Torr. Moreover, the flow rate of the carrier N₂ gas for supplying WCl₆ gas was set to 50 sccm, and the flow rate of H₂ gas was set to 1500 sccm.

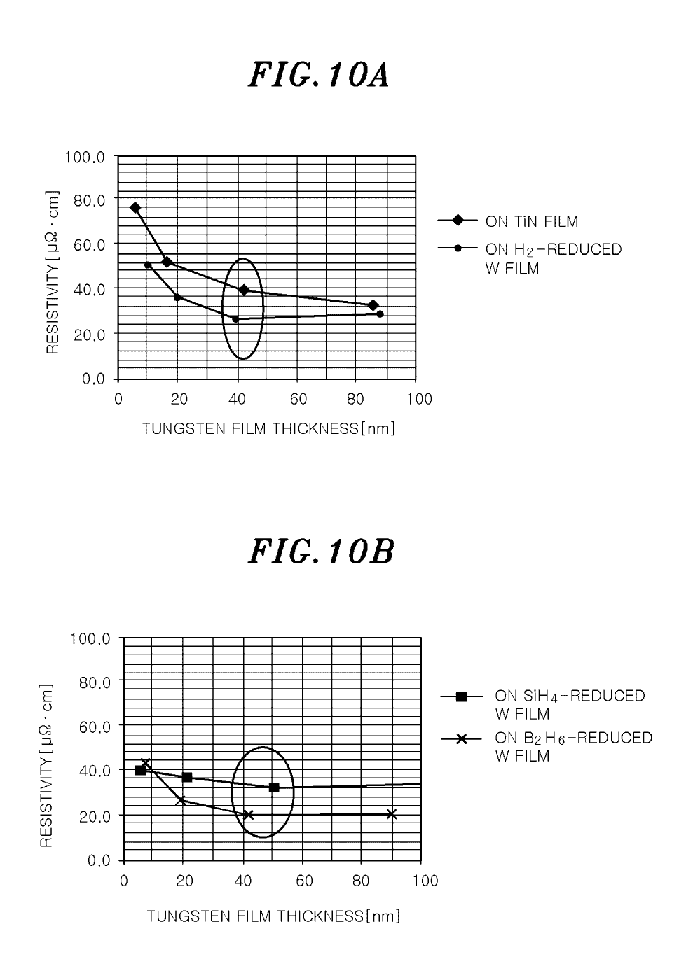

The result thereof is shown in FIGS. 10A and 10B. FIG. 10A shows the relation between the film thickness and the resistivity of a tungsten film in the case of using a TiN film and a H₂-reduced W film as an underlying layer. FIG. 10B shows the relation between the film thickness and the resistivity of a tungsten film in the case of using a SiH₄-reduced W film and a B₂H₆-reduced W film as an underlying layer.

As shown in FIG. 10A, when the film thickness was about 40 nm, the resistivity of the tungsten film formed on the TiN film was 40 μΩ·cm which is a practical level. Further, as shown in FIGS. 10A and 10B, the tungsten film formed on the SiH₄-reduced W film or the B₂H₆-reduced W film had a resistivity lower than that of the tungsten film formed on the TiN film. When the film thickness was about 40 nm, the resistivity of the tungsten film on the SiH₄-reduced W film and that of the tungsten film on the B₂H₆-reduced W film were 30 μΩ·cm and 20 μΩ·cm, respectively, which are lower than that of the tungsten film on the TiN film, i.e., 40 μΩ·cm. This shows that the low resistivity can be obtained by using a SiH₄-reduced W film or a B₂H₆— reduced W film as an underlying layer.

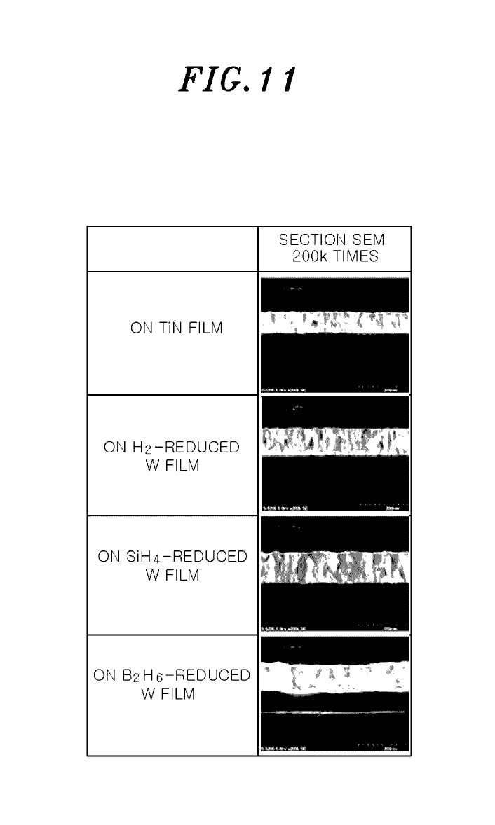

FIG. 11 is an SEM image of the cross section of the tungsten film formed on the underlying layer. As shown in FIG. 11, the crystal grain of the tungsten film formed on the SiH₄-reduced W film or the B₂H₆-reduced W film was greater than that of the tungsten film formed on the TiN film, which resulted in the low resistivity.

### Test Example 7

Here, the effect of the underlying layer was examined.

A tungsten film was formed by an ALD method using WCl₆ gas and H₂ gas while using a TiN film, a TiSiN film and a SiO₂ film as an underlying layer and setting the wafer temperature to 500° C. and the pressure in the chamber to 20 Torr and 30 Torr.

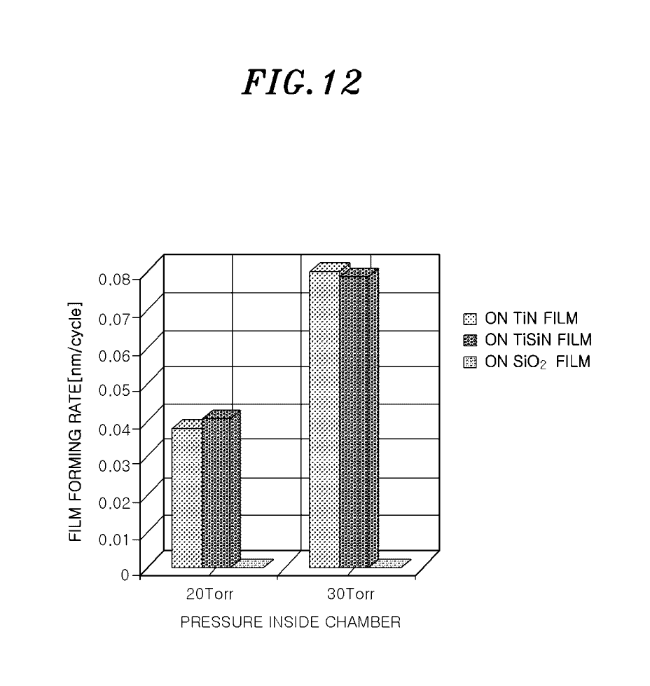

FIG. 12 shows a film forming rate per one cycle in the case of using the above-described films as the underlying layer. As shown in FIG. 12, the film forming rate was considerably varied depending on types of the underlying layer. In the case of using the SiO₂ film, the film formation did not occur at any pressure. On the other hand, in the case of using the TiN film and the TiSiN film, the film formation occurred and the substantially same film forming rate was obtained. Further, in this case, the film forming rate was twice higher when the pressure in the chamber was 30 Torr than when the pressure in the chamber was 20 Torr.

### Test Example 8

Here, a step coverage of a tungsten film was examined. A tungsten film was formed in a hole having a top diameter of 0.18 μm and an aspect ratio of 60 by an ALD method by using the film forming apparatus shown in FIG. 1. At this time, a TiN film was used as an underlying layer and the following conditions were applied.

Wafer temperature: 500° C.

Pressure in a chamber: 30 Torr

Carrier N₂ gas flow rate: 50 sccm

H₂ gas flow rate: 1500 sccm

Duration of WCl₆ supply step (per once): 5 sec

Duration of H₂ gas supply step (per once): 5 sec

Duration of purge step (per once): 10 sec

Number of cycles: 600 times

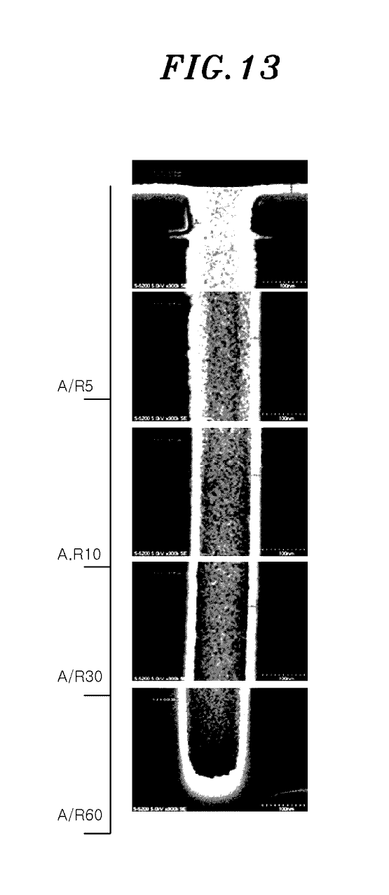

FIG. 13 shows an SEM image of the cross section of the formed tungsten film. As shown in FIG. 13, the tungsten film was formed to reach the bottom of the hole having the top diameter of 0.18 μm and the aspect ratio of 60. Accordingly, a high step coverage can be obtained.

### Test Example 9

Here, impurities of the tungsten film were examined. A TiN film was formed as an underlying layer and a tungsten film was formed by an ALD method by using the film forming apparatus shown in FIG. 1. The film formation condition was the same as that of the test example 8 except that the number of cycles was set to 750 times.

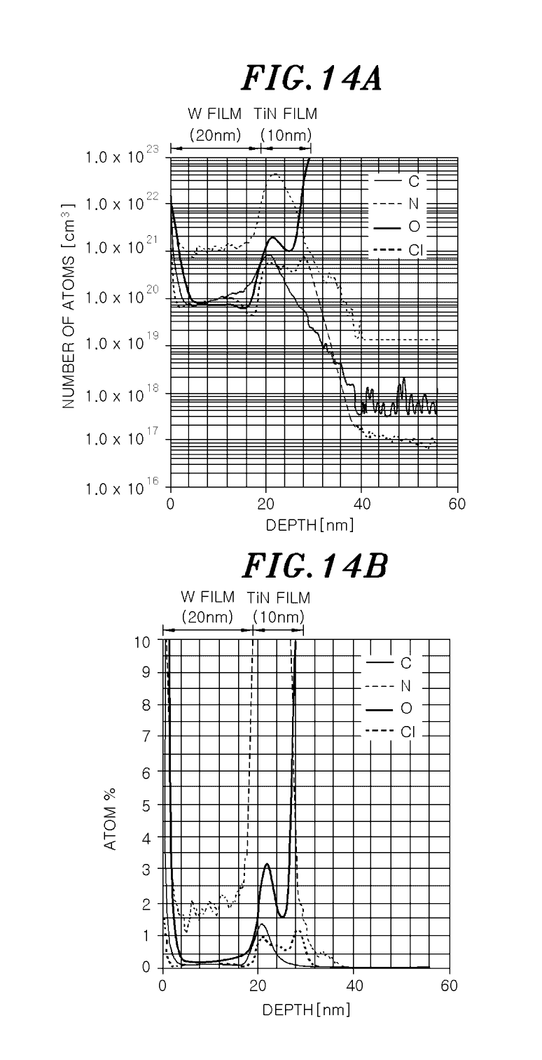

The impurities of the tungsten film thus formed were analyzed in a depth direction by SIMS. The result thereof is shown in FIGS. 14A and 14B. FIG. 14A shows the analysis result as the number of atoms per 1 cm². FIG. 14B shows the analysis result as atomic %.

As shown in FIGS. 14A and 14B, Cl concentration in the W film was 0.1 atomic % to 0.2 atomic %, which is lower than that in the TiN film, i.e., 1.0 atomic %. Further, concentration of O or C in the W film was lower than that in the TiN film. Although concentration of N was about 1.5% to 2%, it is considered to be due to the effect of the TiN film as an underlying layer or the effect of N₂ gas as a carrier gas.

<Other Application>

While the embodiments of the present invention have been described, the present invention may be variously modified without being limited to the above embodiments. For example, although the semiconductor wafer has been described as a substrate to be processed in the above embodiments, the semiconductor wafer may be a silicon substrate or a compound semiconductor such as GaAs, SiC, GaN and the like. Further, the present invention may be applied to a glass substrate for use in FPD (flat-panel display) such as a liquid crystal display and the like, a ceramic substrate or the like without being limited to a semiconductor wafer.

### DESCRIPTION OF REFERENCE NUMERALS

1: chamber
2: susceptor
5: heater
10: shower head
30: gas supply unit
31: film forming material tank
42: H₂ gas supply source
50: control unit
51: process controller
53: storage unit
61, 71: N₂ gas supply source
W: semiconductor wafer

What is claimed is:

1. A tungsten film forming method comprising:
disposing a substrate to be processed in a processing chamber having a reduced pressure atmosphere;
supplying a tungsten chloride gas as a tungsten source and a reducing gas into the processing chamber simultaneously or alternately with a process of purging an inside of the processing chamber interposed therebetween;
heating the substrate; and
forming a tungsten film by causing the tungsten chloride gas and the reducing gas to react with each other on the heated substrate.

2. The tungsten film forming method of claim 1, wherein conditions of a temperature of the substrate and a pressure in the processing chamber are set such that an underlying layer of the tungsten film to be formed is not etched by the tungsten chloride.

3. The tungsten film forming method of claim 1, wherein the tungsten chloride is WCl₆.

4. The tungsten film forming method of claim 1, wherein the substrate has a TiN film or a TiSiN film as the underlying layer of the tungsten film.

5. The tungsten film forming method of claim 1, wherein the temperature of the substrate is 400° C. or above, and the pressure in the processing chamber is 5 Torr or above.

6. The tungsten film forming method of claim 1, wherein the temperature of the substrate is 400° C. or above and the pressure in the processing chamber is 10 Torr or above.

7. The tungsten film forming method of claim 1, wherein the temperature of the substrate is 500° C. or above and the pressure in the processing chamber is 5 Torr or above.

8. The tungsten film forming method of claim 1, wherein the reducing gas is at least one of H₂ gas, SiH₄ gas, B₂H₆ gas, and NH₃ gas.

9. The tungsten film forming method of claim 1, wherein initial film formation is performed by using SiH₄ gas or B₂H₆ gas as the reducing gas and then main film formation is performed by using H₂ gas as the reducing gas.

10. A storage medium storing a computer-executable program for controlling a film forming apparatus, wherein the program, when executed on a computer, controls the film forming apparatus to perform a tungsten film forming method comprising: disposing a substrate to be processed in a processing chamber having a reduced pressure atmosphere; supplying a tungsten chloride gas as a tungsten source and a reducing gas into the processing chamber simultaneously or alternately with a process of purging an inside of the processing chamber interposed therebetween; heating the substrate; and forming a tungsten film by causing the tungsten chloride gas and the reducing gas to react with each other on the heated substrate.
